(19) United States
(12) Patent Application Publication
(10) Pub. No.: US 2026/0362768 A1
(43) Pub. Date: Nov. 12, 2026

(54) SEMICONDUCTOR SUBSTRATE, SEMICONDUCTOR DEVICE, AND METHOD OF MANUFACTURING SEMICONDUCTOR DEVICE

(71) Applicant: Mitsubishi Electric Corporation, Tokyo (JP)

(72) Inventors: Kyohei AKIYOSHI, Tokyo (JP); Takanori TANAKA, Tokyo (JP); Kazumasa IWANAGA, Tokyo (JP)

(73) Assignee: Mitsubishi Electric Corporation, Tokyo (JP)

(21) Appl. No.: 19/546,514

(22) Filed: Feb. 23, 2026

(30) Foreign Application Priority Data
May 9, 2025 (JP) 2025-078409

(51) Int. Cl. H10D 62/40; H10D 62/00

(52) U.S. Cl. CPC H10D 62/40; H10D 62/052

(57) ABSTRACT

A semiconductor substrate includes a single crystal semiconductor substrate and a polycrystalline semiconductor layer. The single crystal semiconductor substrate includes a first main surface, a second main surface opposite to the first main surface, and an outer peripheral surface connecting the first main surface and the second main surface. The polycrystalline semiconductor layer is provided on the outer peripheral surface of the single crystal semiconductor substrate.

### BACKGROUND

### Technical Field

The present disclosure relates to a semiconductor substrate, a semiconductor device, and a method of manufacturing a semiconductor device.

### Description of the Background Art

Japanese Patent Application No. 6-120097 (1994) discloses a substrate for a semiconductor device in which 20 nm of a silicon oxide film and 50 nm of a polycrystalline silicon film are formed by a CVD method in a portion of a silicon substrate (corresponding to a semiconductor substrate) excluding a peripheral portion of the surface. With this configuration, damages generated at the time of contact between a support of the substrate and the substrate during the heat treatment are suppressed.

However, Japanese Patent Application No. 6-120097 (1994) does not describe a problem that occurs when a semiconductor substrate having a diameter smaller than the standard is handled with a semiconductor manufacturing apparatus. Thus, in the technique described in Japanese Patent Application No. 6-120097 (1994), a semiconductor substrate having a diameter smaller than the standard has a problem that an error related to the diameter of the semiconductor substrate occurs at the time of conveyance or processing in a semiconductor manufacturing apparatus that conveys and processes a semiconductor substrate within the standard, and the semiconductor substrate having a diameter smaller than the standard cannot be conveyed or processed.

### SUMMARY

An object of the present disclosure is to provide a technique capable of conveying and processing a semiconductor substrate having a diameter smaller than the standard in a semiconductor manufacturing apparatus that conveys and processes a semiconductor substrate within the standard.

A semiconductor substrate according to the present disclosure includes a single crystal semiconductor substrate including a first main surface, a second main surface opposite to the first main surface, and an outer peripheral surface connecting the first main surface and the second main surface, and a polycrystalline semiconductor layer provided on the outer peripheral surface of the single crystal semiconductor substrate.

According to the present disclosure, the diameter of the semiconductor substrate is increased by the polycrystalline semiconductor layer, and thus, it is possible to convey and process the semiconductor substrate including a single crystal semiconductor substrate having a diameter smaller than the standard in a semiconductor manufacturing apparatus that conveys and processes a semiconductor substrate within the standard.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a flowchart illustrating a method of manufacturing a semiconductor device according to a first preferred embodiment;

FIG. 2 is a top view of a single crystal semiconductor substrate after a semiconductor substrate preparation step in the first preferred embodiment;

FIG. 3 is a sectional view of the single crystal semiconductor substrate after the semiconductor substrate preparation step in the first preferred embodiment;

FIG. 4 is a sectional view of a semiconductor substrate after a polycrystalline semiconductor layer formation step in the first preferred embodiment;

FIG. 5 is a sectional view of the semiconductor substrate after a grinding step in the first preferred embodiment;

FIG. 6 is a sectional view of the semiconductor substrate after a polishing step in the first preferred embodiment;

FIG. 7 is a sectional view illustrating another example of the semiconductor substrate after the grinding step in the first preferred embodiment;

FIG. 8 is a sectional view of the semiconductor substrate after an epitaxial growth step in the first preferred embodiment;

FIG. 9 is a sectional view of the semiconductor substrate after a semiconductor element formation step in the first preferred embodiment;

FIG. 10 is a sectional view of the semiconductor substrate after the grinding step in the first preferred embodiment;

FIG. 11 is a sectional view of the semiconductor substrate after the grinding step is performed after edge processing in the first preferred embodiment;

FIG. 12 is a sectional view illustrating another example of the semiconductor substrate after the grinding step is performed after edge processing in the first preferred embodiment;

FIG. 13 is a flowchart illustrating a method of manufacturing a semiconductor device according to a second preferred embodiment;

FIG. 14 is a sectional view of the semiconductor substrate after a hydrogen ion layer formation step in the second preferred embodiment;

FIG. 15 is a sectional view of the semiconductor substrate after a polycrystalline semiconductor layer formation step in the second preferred embodiment;

FIG. 16 is a sectional view of the semiconductor substrate after a peeling step in the second preferred embodiment;

FIG. 17 is a flowchart illustrating a method of manufacturing a semiconductor device according to a third preferred embodiment;

FIG. 18 is a sectional view of a semiconductor substrate after a semiconductor substrate preparation step in the third preferred embodiment;

FIG. 19 is a sectional view of the semiconductor substrate after a polycrystalline semiconductor layer formation step in the third preferred embodiment; and

FIG. 20 is a sectional view of the semiconductor substrate after a peeling step in the third preferred embodiment.

### DESCRIPTION OF THE PREFERRED EMBODIMENTS

### First Preferred Embodiment

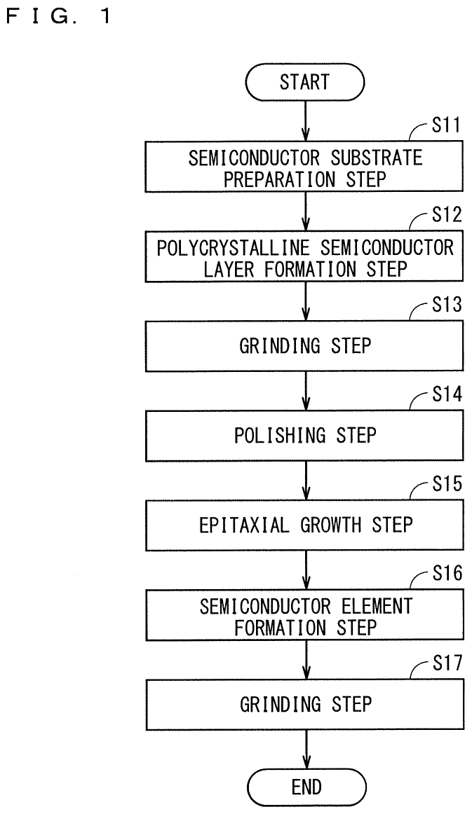

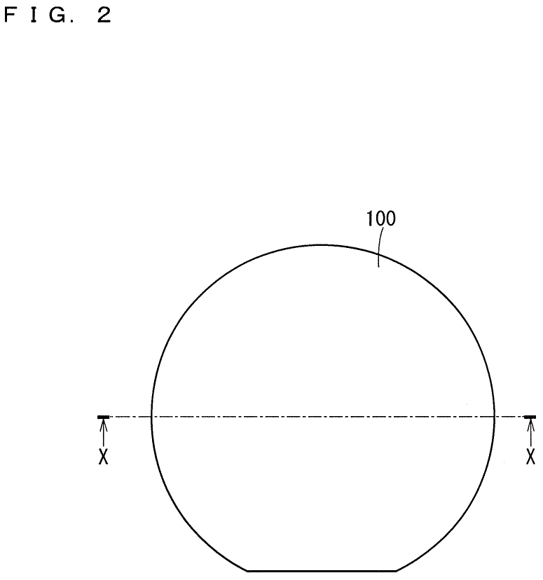

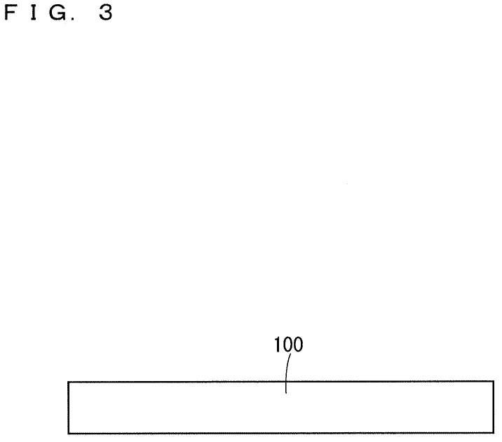

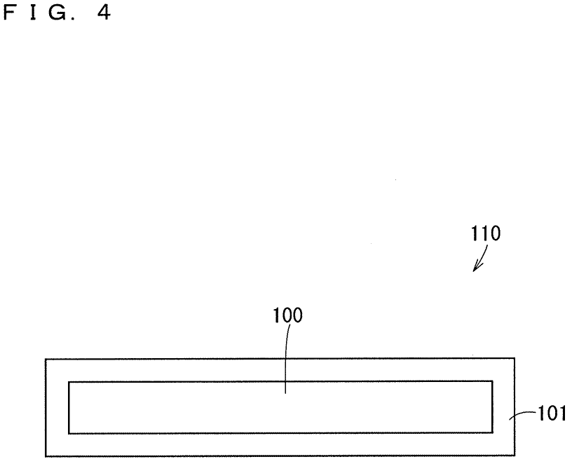

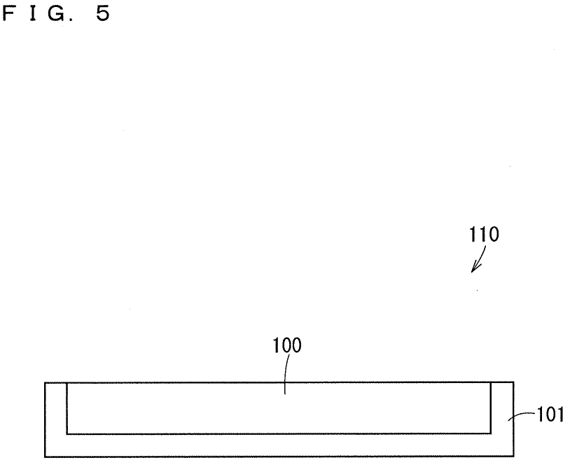

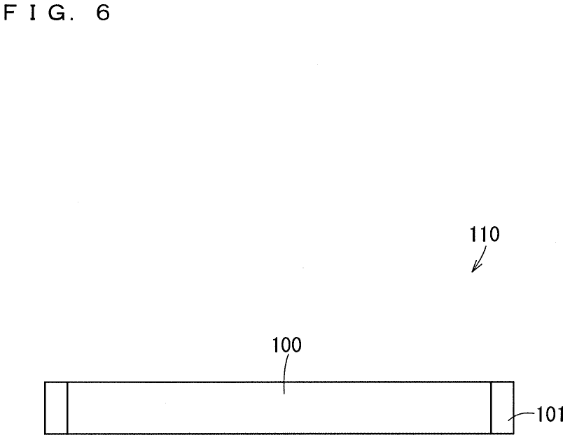

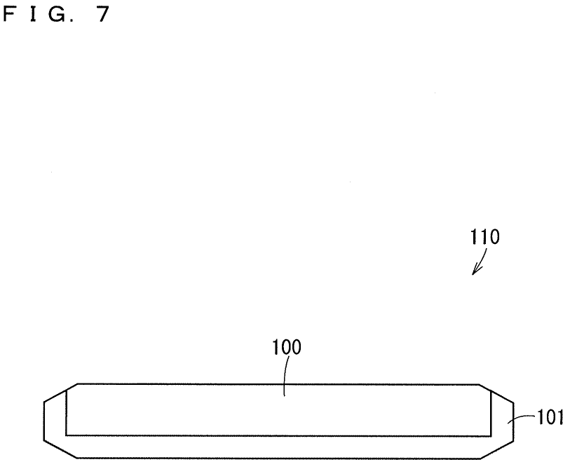

A first preferred embodiment will be described below with reference to the drawings. FIG. 1 is a flowchart illustrating a method of manufacturing a semiconductor device 111 according to the first preferred embodiment. FIG. 2 is a top view of a single crystal semiconductor substrate 100 after a semiconductor substrate preparation step in the first preferred embodiment. FIG. 3 is a sectional view of the single crystal semiconductor substrate 100 after the semiconductor substrate preparation step in the first preferred embodiment, which is a sectional view taken along the line X-X in FIG. 2. FIG. 4 is a sectional view of the semiconductor substrate 110 after the polycrystalline semiconductor layer formation step in the first preferred embodiment. FIG. 5 is a sectional view of the semiconductor substrate 110 after a grinding step in the first preferred embodiment. FIG. 6 is a sectional view of the semiconductor substrate 110 after a polishing step in the first preferred embodiment. FIG. 7 is a sectional view illustrating another example of the semiconductor substrate 110 after the grinding step in the first preferred embodiment. <Method of manufacturing and structure>

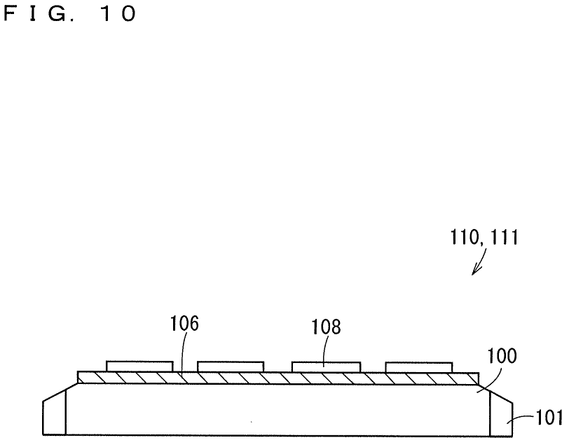

As illustrated in FIG. 1, a method of manufacturing the semiconductor device 111 (see FIG. 10) includes a semiconductor substrate preparation step (step S11), a polycrystalline semiconductor layer formation step (step S12), a grinding step (step S13), a polishing step (step S14), an epitaxial growth step (step S15), a semiconductor element formation step (step S16), and a grinding step (step S17). Among these, the semiconductor substrate preparation step (step S11) to the grinding step (step S13) are regarded as the method of manufacturing the semiconductor substrate 110 (see FIG. 5).

First, in the semiconductor substrate preparation step (step S11), as illustrated in FIGS. 2 and 3, a single crystal semiconductor substrate 100 is prepared. The single crystal semiconductor substrate 100 is formed in a substantially disk shape having a first main surface, a second main surface opposite to the first main surface, and an outer peripheral surface connecting the first main surface and the second main surface. Here, the first main surface is a front surface, and the second main surface is a back surface.

Next, in the polycrystalline semiconductor layer formation step (step S12), as illustrated in FIG. 4, a polycrystalline semiconductor layer 101 is formed on the first main surface, the second main surface, and the outer peripheral surface of the single crystal semiconductor substrate 100.

Hereinafter, a case where both the single crystal semiconductor substrate 100 and the polycrystalline semiconductor layer 101 are made of silicon carbide will be described, but both of them may be formed of another semiconductor material or a ceramic material. Examples of another semiconductor material include silicon, a gallium nitride-based material, a gallium oxide-based material, and diamond. Examples of the ceramic material include α-Al₂O₃ (sapphire).

The material of the single crystal semiconductor substrate 100 and the material of the polycrystalline semiconductor layer 101 may be different from each other. The use of different materials makes it possible to form the single crystal semiconductor substrate 100 and the polycrystalline semiconductor layer 101 at low cost as compared with the case of using the same type of materials in some cases. When the semiconductor substrate 110 according to the first preferred embodiment is processed at a high temperature, it is preferable to use materials with which physical properties of the single crystal semiconductor substrate 100 and the polycrystalline semiconductor layer 101 are relatively close to each other. The physical properties include, for example, a thermal expansion coefficient and a melting point.

When silicon carbide is used as the material, it may be 15R-SiC or hexagonal polytype silicon carbide. For example, 2H-SiC, 4H-SiC, or 6H-SiC may be used. The dopant atoms may include, for example, nitrogen, phosphorus, beryllium, boron, aluminum, or gallium. In addition, it may contain unnecessary impurities, for example, hydrogen, fluorine, or oxygen.

The c-plane may have an off angle, and the off angle is preferably in an a-axis direction ([11-20] direction) of the silicon carbide single crystal. The off angle may be more than 0° and 10° or less, preferably 5° or less, more preferably 2° or more and 4.5° or less.

The diameter of the single crystal semiconductor substrate 100 preferably corresponds to the standard as the production standard, and it may be 2 inches (50 mm), 3 inches (75 mm), 4 inches (100 mm), 5 inches (125 mm), 6 inches (150 mm), 7 inches (175 mm), 8 inches (200 mm), or 12 inches (300 mm).

However, the effect of the first preferred embodiment is obtained when the diameter is smaller than the standard. To obtain the effect of the first preferred embodiment, the diameter is smaller than the standard preferably by 1 μm or more and 2000 μm or less, more preferably by 1 μm or more and 1500 μm or less. The diameter is smaller than the standard still more preferably by 1 μm or more and 1000 μm or less.

In the first preferred embodiment, the diameter is smaller than the standard preferably by 2000μm or less, more preferably by 1500 μm or less, because in the polycrystalline semiconductor layer formation step (step S12), the polycrystalline semiconductor layer 101 is grown to increase the diameter of the semiconductor substrate 110, and it is difficult to control the in-plane growth amount in the semiconductor substrate 110 when the polycrystalline semiconductor layer 101 is grown to 2000 μm or more. The diameter is smaller than the standard still more preferably by 1000 μm or less.

A notch or an orientation flat used for positioning in the semiconductor manufacturing apparatus may be formed on a part of the outer periphery of the semiconductor substrate 110. In addition, printing for identifying the semiconductor substrate 100 may be performed on one or both of the first main surface and the second main surface of the semiconductor substrate 110. With the printing, the plane orientation of the semiconductor substrate 110 can be identified, and the individual semiconductor substrate 110 can be identified.

The thickness of the single crystal semiconductor substrate 100 is preferably 50 μm or more and 1000 μm or less, more preferably 100 μm or more and 800 μm or less, still more preferably 200 μm or more and 600 μm or less. This is because, in the grinding step (step S17) described later, it is necessary to remove the polycrystalline semiconductor layer 101 by performing grinding thicker than the thickness of the polycrystalline semiconductor layer 101 to make the characteristics of the semiconductor device 111 manufactured from the semiconductor substrate 110 according to the first preferred embodiment the same as the characteristics of the semiconductor device manufactured from the semiconductor substrate including only the single crystal semiconductor substrate 100. Since the thickness of a general semiconductor device is 50 μm or more, the thickness of the single crystal semiconductor substrate 100 is preferably 50 μm or more.

The first main surface and the second main surface of the single crystal semiconductor substrate 100 may be subjected to grinding processing or chemical mechanical polishing (CMP), and the adhesion between the single crystal semiconductor substrate 100 and the polycrystalline semiconductor layer 101 is improved as the surface roughness is higher in the polycrystalline semiconductor formation step (step S12). Specifically, the surface roughness is preferably 0.05 nm or more, more preferably 0.1 nm or more. Further, the surface roughness is more preferably 0.5 nm or more, 1 nm or more, 3 nm or more, or 5 nm or more.

The outer peripheral surface of the single crystal semiconductor substrate 100 may have a tapered shape. With the tapered shape, alignment can be performed in a semiconductor manufacturing apparatus in the same manner as in the case of using a typical semiconductor substrate, and there is an effect of preventing chipping due to impact during conveyance or processing.

A growth method of the polycrystalline semiconductor layer 101 is, specifically, physical vapor deposition (PVD) or chemical vapor deposition (CVD). CVD is preferably used because CVD achieves a higher growth rate and higher adhesion than PVD.

The polycrystalline semiconductor layer 101 is preferably grown to a size with which the diameter of the semiconductor substrate 110 is equal to or larger than the diameter corresponding to the standard. For example, when the standard of the semiconductor substrate that can be conveyed and processed by the semiconductor manufacturing apparatus is 8 inches (200 mm), and the diameter of the single crystal semiconductor substrate 100 is 199 mm, the growth amount of the polycrystalline semiconductor layer 101 is preferably 1 mm or more.

The reason of the diameter set to 1 mm or more instead of 1 mm is that the diameter can be adjusted to 200 mm in the subsequent grinding step (step S17) by growing the semiconductor substrate 110 by 1 mm or more to form the semiconductor substrate 110 having a diameter of 200 mm or more.

The growth amounts in the diameter direction and the thickness direction of the polycrystalline semiconductor layer 101 do not have to be isotropic, and the polycrystalline semiconductor layer 101 may be grown anisotropically through temperature control of a CVD furnace or gas flow rate adjustment. For example, when the diameter of the single crystal semiconductor substrate 100 is small, and the thickness is large, correction of warpage due to the growth of the polycrystalline semiconductor layer 101 in the thickness direction is unnecessary, and thus, the polycrystalline semiconductor layer 101 may be grown larger in the diameter direction than in the thickness direction.

Next, in the grinding step (step S13) as a first grinding step, the polycrystalline semiconductor layer 101 and the single crystal semiconductor substrate 100 on the first main surface side of the single crystal semiconductor substrate 100 are ground by a thickness thicker than the thicknesses of the polycrystalline semiconductor layer 101 formed on the first main surface, the second main surface, and the outer peripheral surface of the single crystal semiconductor substrate 100 illustrated in FIG. 4. As a result, the first main surface of the single crystal semiconductor substrate 100 is exposed as illustrated in FIG. 5.

Alternatively, in the grinding step (step S13), the polycrystalline semiconductor layer 101 and the single crystal semiconductor substrate 100 on the first main surface side and the second main surface side of the single crystal semiconductor substrate 100 may be ground by a thickness thicker than the thickness of the polycrystalline semiconductor layer 101. In this case, as illustrated in FIG. 6, the first main surface and the second main surface of the single crystal semiconductor substrate 100 are exposed. That is, the polycrystalline semiconductor layer 101 is not provided on the first main surface and the second main surface of the single crystal semiconductor substrate 100. Alternatively, the structure of FIG. 5 may be maintained by performing grinding to such an extent that the second main surface is not exposed.

By forming the polycrystalline semiconductor layer 101 in the diameter direction of the single crystal semiconductor substrate 100 having a diameter smaller than the standard like this, the semiconductor substrate 110 has a diameter corresponding to the standard, and the semiconductor substrate 110 can be conveyed and processed with the semiconductor manufacturing apparatus corresponding to the standard.

When the thickness of the single crystal semiconductor substrate 100 is small, and the semiconductor substrate 110 warps in the semiconductor manufacturing step, as illustrated in FIG. 5, there is an effect of increasing the thickness of the semiconductor substrate 110 and suppressing the warpage by leaving the polycrystalline semiconductor layer 101 on the second main surface side. Specifically, the thickness of the polycrystalline semiconductor layer 101 is preferably 20 μm or more and 1000 μm or less, more preferably 50 μm or more and 800 μm or less, still more preferably 100 μm or more and 500 μm or less.

The thickness of the polycrystalline semiconductor layer 101 is not the thickness of the polycrystalline semiconductor layer 101 provided on the outer peripheral surface of the single crystal semiconductor substrate 100, but is, for example, the thickness of the polycrystalline semiconductor layer 101 provided on the second main surface of the single crystal semiconductor substrate 100. When the thickness of the polycrystalline semiconductor layer 101 is 20 μm or more, an effect of suppressing warpage of the semiconductor substrate 103 can be obtained. On the other hand, efficiency in production is reduced when the thickness of the polycrystalline semiconductor layer 101 is 1000 μm or more, and thus, the thickness is desirably less than 1000 μm.

The single crystal semiconductor layer 101 may be used in a state immediately after CVD growth, or may be subjected to grinding or CMP. When the single crystal semiconductor layer 101 is used in a state immediately after CVD growth, the number of steps of the process is smaller than that when grinding or CMP is performed, and thus, the cost can be reduced. On the other hand, when an adsorption error occurs in the subsequent process because of the unevenness of the surface in a state immediately after the CVD growth, adsorption can be realized by flattening the surface by grinding. Further, when CMP is performed, there is an effect of reducing warpage by relaxing stress by treating surface damage caused by grinding.

Either the thickness of the single crystal semiconductor substrate 100 or the thickness of the polycrystalline semiconductor layer 101 may be larger.

In the polycrystalline semiconductor layer formation step (step S12), the polycrystalline semiconductor layer 101 grown on the first main surface side of the single crystal semiconductor substrate 100 is grown thinner and anisotropically than the polycrystalline semiconductor layer 101 grown on the second main surface side by controlling the temperature of the CVD furnace or the gas flow rate. As a result, when the semiconductor substrate 110 is formed, the grinding amount of the polycrystalline semiconductor layer 101 on the first main surface side can be reduced.

In addition, the grinding step (step S13) can be omitted, or the grinding amount can be reduced by masking the first main surface side or both the first main surface side and the second main surface side of the single crystal semiconductor substrate 100 with a carbon sheet or the like to suppress the growth of the polycrystalline semiconductor layer 101 in the polycrystalline semiconductor layer formation step (step S12). As a result, the semiconductor substrate 110 illustrated in FIG. 5 and the semiconductor substrate 110 illustrated in FIG. 6 can be efficiently manufactured. The masking method is not limited to the carbon sheet, but for example, a mask material such as carbon may be formed by film formation, coating, or the like.

The total thickness variation (TTV) indicating the difference in thickness between the thickest portion and the thinnest portion in the semiconductor substrate 110 after the grinding step is preferably 3 μm or less, more preferably 2 μm or less, still more preferably 1 μm or less. When the TTV is 3μm or less, defocus caused by the stepper apparatus for the photolithography process in the semiconductor element formation step (step S16) described later can be suppressed, and thus, defective chips can be reduced.

In the semiconductor substrate 110 illustrated in FIG. 5, printing for identifying the semiconductor substrate 110 may be performed on one or both of the first main surface side and the second main surface side. With the printing, the plane orientation of the semiconductor substrate 110 can be identified, and the individual semiconductor substrate 110 can be identified.

In the grinding step (step S13), as illustrated in FIG. 7, an end portion of the semiconductor substrate 110 may also be ground to form the semiconductor substrate 110 in a tapered shape. By forming the tapered shape, alignment can be performed in a semiconductor manufacturing apparatus in the same manner as in the case of using a typical single crystal semiconductor substrate, and there is an effect of preventing chipping due to impact when the semiconductor substrate 110 is conveyed or handled.

The processing on the end portion may be performed in any step of the polycrystalline semiconductor forming step (step S12) to the epitaxial growth step (step S15) described later. The following steps will be described using the semiconductor substrate 110 having a tapered shape illustrated in FIG. 7.

The formation of the tapered shape can be performed with, for example, an apparatus in which a grinding wheel having any shape is attached to a rotary edge processing machine. At the same time, the tapered shape may be adjusted by grinding the orientation flat or the notch so that the semiconductor substrate can be aligned in the semiconductor manufacturing apparatus. The orientation flat or the notch may or may not be provided with the polycrystalline semiconductor layer 101.

The semiconductor substrate preparation step (step S11) to the grinding step (step S13) described above are regarded as a method of manufacturing the semiconductor substrate 110 in the method of manufacturing the semiconductor device 111 (see FIG. 10).

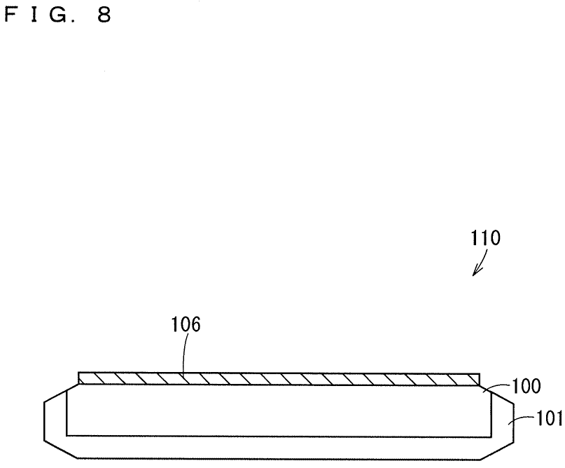

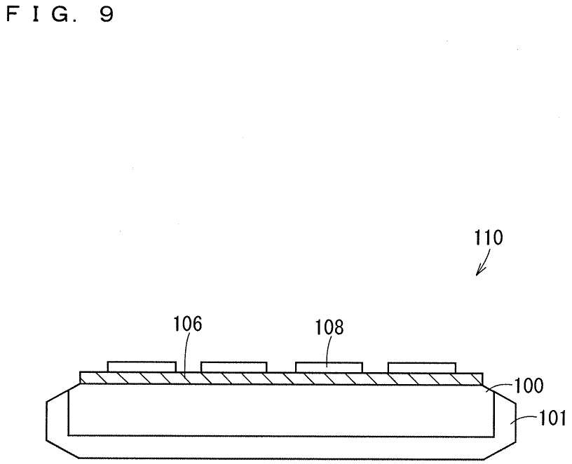

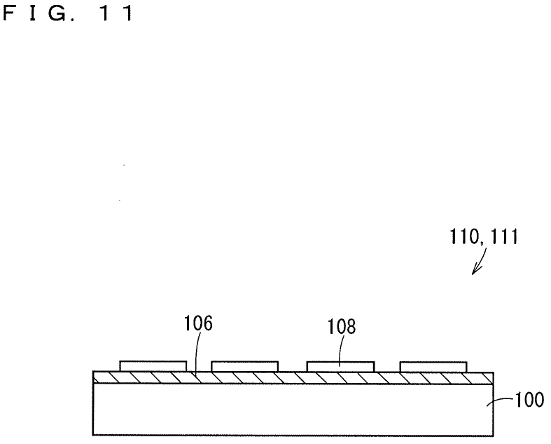

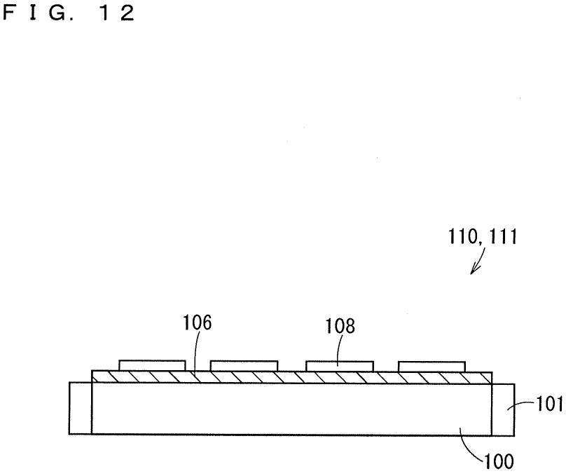

Next, subsequent steps will be described. FIG. 8 is a sectional view of the semiconductor substrate 110 after the epitaxial growth step in the first preferred embodiment. FIG. 9 is a sectional view of the semiconductor substrate 110 after the semiconductor element formation step in the first preferred embodiment. FIG. 10 is a sectional view of the semiconductor substrate 110 after the grinding step in the first preferred embodiment. FIG. 11 is a sectional view of the semiconductor substrate 110 after the grinding step is performed after edge processing in the first preferred embodiment. FIG. 12 is a sectional view illustrating another example of the semiconductor substrate 110 after the grinding step is performed after edge processing in the first preferred embodiment.

In the polishing step (step S14), the first main surface or both the first main surface and the second main surface of the semiconductor substrate 110 illustrated in FIG. 7 are chemically and mechanically polished. This allows an epitaxial layer 106 (see FIG. 8) having few crystal defects to grow in the epitaxial growth step (step S15), which is the next step. Specifically, the surface roughness after chemical and mechanical polishing is 1 nm or less, more preferably 0.5 nm or less. Further, the surface roughness is more preferably 0.3 nm or less, 0.15 nm or less, or 0.1 nm or less.

Next, in the epitaxial growth step (step S15), as illustrated in FIG. 8, the epitaxial layer 106 is formed on the first main surface of the single crystal semiconductor substrate 100 that has been polished.

Next, in the semiconductor element formation step (step S16), as illustrated in FIG. 9, the semiconductor element 108 is formed on the epitaxial layer 106 to form the semiconductor substrate 110 on which the semiconductor element 108 is formed. Formation of the semiconductor element 108 includes ion implantation and formation of a surface electrode. The semiconductor element 108 is, for example, a power device such as a metal oxide semiconductor field effect transistor (MOSFET), a diode, or an insulated gate bipolar transistor (IGBT). When gallium nitride is used instead of silicon carbide as the semiconductor material of the single crystal semiconductor substrate 100, the semiconductor element 108 is, for example, a gallium nitride high-frequency device. In the case of the single crystal semiconductor substrate 100 made of silicon carbide as well, a gallium nitride high-frequency device may be formed.

Next, in the grinding step (step S17) as a second grinding step, the polycrystalline semiconductor layer 101 on the second main surface side of the semiconductor substrate 110 on which the semiconductor element 108 is formed on the first main surface as illustrated in FIG. 9 is ground so as to have any thickness, whereby the semiconductor substrate 110 illustrated in FIG. 10, that is, the semiconductor device 111 is formed. The thickness of the semiconductor substrate 110 at this time is generally 50 μm or more and 300 μm or less, and it is necessary to grind the polycrystalline semiconductor layer 101 and the single crystal semiconductor substrate 100 on the second main surface side of the single crystal semiconductor substrate 100 by a thickness thicker than the thickness of the polycrystalline semiconductor layer 101 to expose the second main surface of the single crystal semiconductor substrate 100. This is to make the semiconductor substrate 110 have the same characteristics as the characteristics of the semiconductor element 108 formed on the semiconductor substrate formed only of the single crystal semiconductor substrate 100 by not including the polycrystalline semiconductor layer 101 in the thickness direction of the final semiconductor substrate 110.

When the end portion of the semiconductor substrate 110 has a sharp knife-like edge after grinding, it is preferable to process the end portion from a tapered shape to a vertical shape by grinding the end portion before grinding. When the knife-like edge is conveyed or processed in the subsequent electrode formation step to be performed on the second main surface side, the knife-like edge may be broken or cracked because of impact.

When edge processing is performed before grinding, the polycrystalline semiconductor layer 101 on the outer peripheral surface of the semiconductor substrate 110 is completely removed, and the semiconductor substrate 110 illustrated in FIG. 11 of only the single crystal semiconductor substrate 100 is formed when the thickness of the polycrystalline semiconductor layer 101 on the outer peripheral surface of the semiconductor substrate 110 illustrated in FIG. 9 is small.

On the other hand, when the thickness of the polycrystalline semiconductor layer 101 on the outer peripheral surface of the semiconductor substrate 110 illustrated in FIG. 9 is large, the polycrystalline semiconductor layer 101 on the outer peripheral surface of the semiconductor substrate 110 remains, and the semiconductor substrate 110 illustrated in FIG. 12 is formed. The polycrystalline semiconductor layer 101 is not included in the thickness direction in the semiconductor substrate 110 illustrated in FIG. 11 or the semiconductor substrate 110 illustrated in FIG. 12, and thus, there is no influence on the characteristics of the semiconductor element 108.

### Effects

As described above, in the first preferred embodiment, the semiconductor substrate 110 includes the single crystal semiconductor substrate 100 having the first main surface, the second main surface opposite to the first main surface, and the outer peripheral surface connecting the first main surface and the second main surface, and the polycrystalline semiconductor layer 101 provided on the outer peripheral surface of the single crystal semiconductor substrate 100. The polycrystalline semiconductor layer 101 is not provided on the first main surface and the second main surface of the single crystal semiconductor substrate 100.

Thus, the diameter of the semiconductor substrate 110 is increased by the polycrystalline semiconductor layer 101, and thus, the semiconductor substrate 110 including the single crystal semiconductor substrate 100 having a diameter smaller than the standard can be conveyed and processed in a semiconductor manufacturing apparatus that conveys and processes a semiconductor substrate within the standard.

In addition, because the polycrystalline semiconductor layer 101 is further provided on the second main surface of the single crystal semiconductor substrate 100, the semiconductor substrate 110 is easily handled in which the warpage of the semiconductor substrate 110 is suppressed.

In addition, because the epitaxial layer 106 is provided on the first main surface of the single crystal semiconductor substrate 100, the semiconductor element 108 can be provided on the epitaxial layer 106.

In addition, because the single crystal semiconductor substrate 100 and the polycrystalline semiconductor layer 101 are made of the same material, physical characteristics such as a melting point and a thermal expansion coefficient are close to each other.

In addition, because the single crystal semiconductor substrate 100 and the polycrystalline semiconductor layer 101 are made of materials different from each other, the single crystal semiconductor substrate 100 and the polycrystalline semiconductor layer 101 can be formed at low cost by using different materials as compared with the case of using the same type of materials.

In addition, because the thickness of the single crystal semiconductor substrate 100 is 50 μm or more, the characteristics of the semiconductor substrate 110 can be made the same as the characteristics of the semiconductor substrate manufactured only from the single crystal semiconductor substrate 100 by making the thickness of the semiconductor substrate 110 the same as the thickness of the semiconductor substrate manufactured only from the single crystal semiconductor substrate 100.

In addition, because the thickness of the polycrystalline semiconductor layer 101 is 50 μm or more, warpage of the semiconductor substrate 110 can be suppressed.

### Second Preferred Embodiment

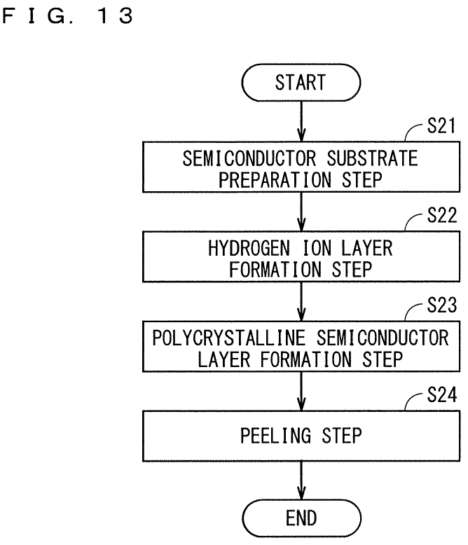

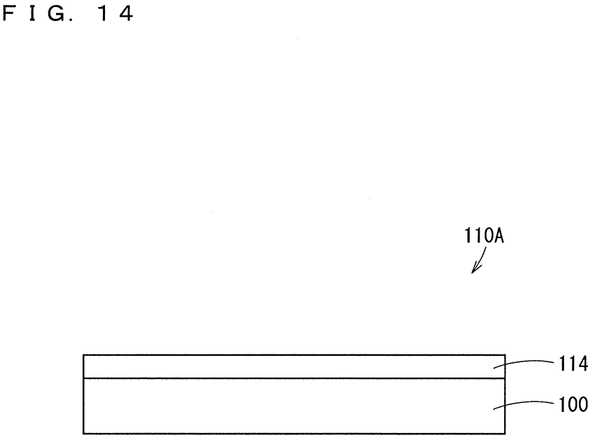

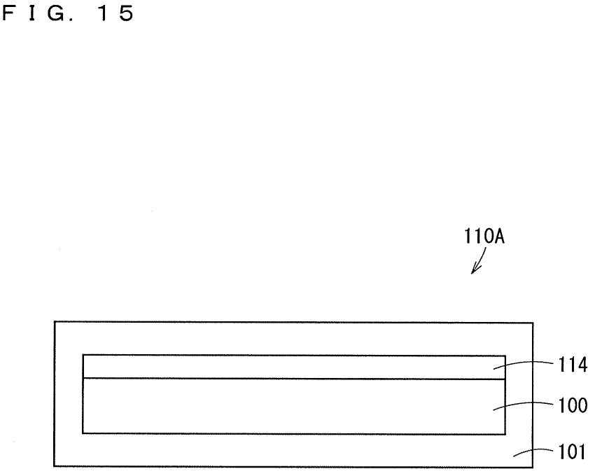

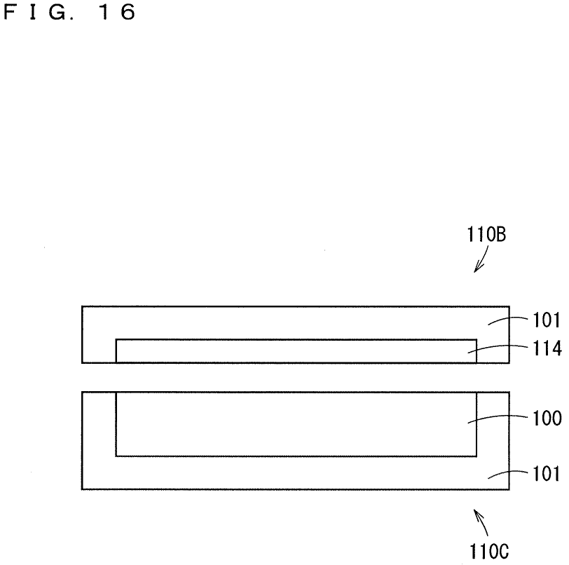

Next, a second preferred embodiment will be described. FIG. 13 is a flowchart illustrating a method of manufacturing the semiconductor device 111 according to the second preferred embodiment. FIG. 14 is a sectional view of a semiconductor substrate 110A after a hydrogen ion layer formation step in the second preferred embodiment. FIG. 15 is a sectional view of the semiconductor substrate 110A after a polycrystalline semiconductor layer formation step in the second preferred embodiment. FIG. 16 is a sectional view of the semiconductor substrates 110B, 110C after a peeling step in the second preferred embodiment. In the second preferred embodiment, the same components as those described in the first preferred embodiment are denoted by the same reference numerals, and description thereof is omitted.

### Method of Manufacturing and Structure

As illustrated in FIG. 13, in the second preferred embodiment, a semiconductor substrate 110A is manufactured by a method different from that of the first preferred embodiment. In the first preferred embodiment, the method of manufacturing the semiconductor substrate 110 has been described in the method of manufacturing the semiconductor device 111, but in the second preferred embodiment, only the method of manufacturing the semiconductor substrate 110A will be described.

In a semiconductor substrate preparation step (step S21), the single crystal semiconductor substrate 100 illustrated in FIGS. 2 and 3 is prepared in the same manner as in step S11 in FIG. 1.

Next, in a hydrogen ion layer formation step (step S22), ions of a light species are implanted into the first main surface of the single crystal semiconductor substrate 100 illustrated in FIGS. 2 and 3, and thus, an ion implantation layer 114 as a hydrogen ion layer is formed on the first main surface of the single crystal semiconductor substrate 100 as illustrated in FIG. 14. The ions of the light species are, for example, hydrogen or helium, and they may be co-implanted. The implantation energy of the light species is selected to ensure that the ions reach a predetermined depth in the first main surface of the single crystal semiconductor substrate 100. Typically, hydrogen ions are implanted with an energy included within 10 keV or more and 250 keV or less and a dose amount included within 5E16/cm² or more and 1E17/cm² or less, whereby hydrogen ions reach a depth of 0.1 μm or more and 1.5 μm or less.

The subsequent polycrystalline semiconductor layer formation step (step S23) is the same as the polycrystalline semiconductor layer formation step (step S12) in FIG. 1. FIG. 15 illustrates the semiconductor substrate 110A in which the polycrystalline semiconductor layer 101 is grown on the ion-implanted single crystal semiconductor substrate 100.

Next, in the peeling step (step S24), the single crystal semiconductor substrate 100, specifically, the semiconductor substrate 110A is heated at a high temperature to peel the substrate along the ion implantation layer 114, whereby the first main surface is exposed. More specifically, under an inert atmosphere filled with an argon gas, the single crystal semiconductor substrate 100 on which the polycrystalline semiconductor layer 101 is formed is heated to 1500 °C or higher to form a microbubble layer in the ion implantation layer 114, whereby a semiconductor substrate 110B in which the second main surface and the outer peripheral surface are covered with the polycrystalline semiconductor layer 101 and a semiconductor substrate 110C in which the first main surface and the outer peripheral surface are covered with the polycrystalline semiconductor layer 101 are obtained as illustrated in FIG. 16.

In the second preferred embodiment as well, similarly to FIG. 6, the grinding step may be performed on the semiconductor substrate 110C to grind the polycrystalline semiconductor layer 101 and the single crystal semiconductor substrate 100 on the second main surface side of the single crystal semiconductor substrate 100.

### Effects

As described above, the semiconductor substrate 110C of the second preferred embodiment has the same structure as the semiconductor substrate 110 of the first preferred embodiment, and the same effect can be obtained.

In addition, the semiconductor substrate 110B can be utilized as a dummy substrate used for checking conveyance or processing in the semiconductor manufacturing apparatus, and the cost of separately purchasing a dummy substrate can be reduced.

### Third Preferred Embodiment

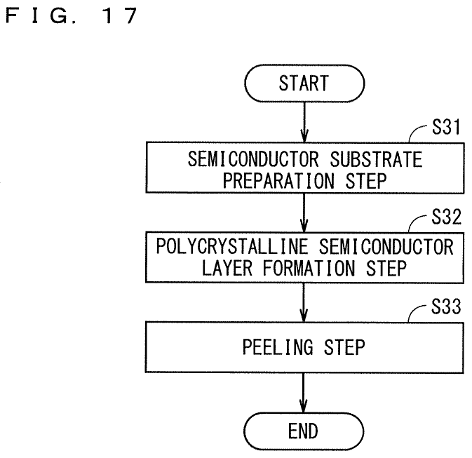

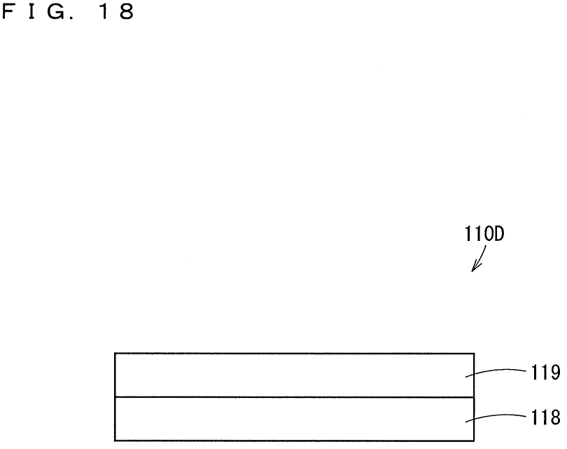

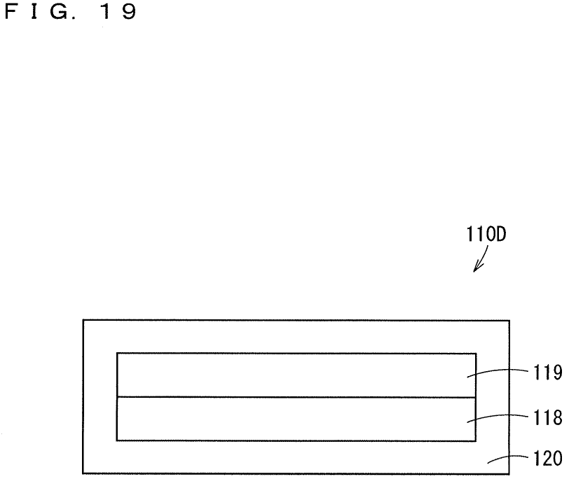

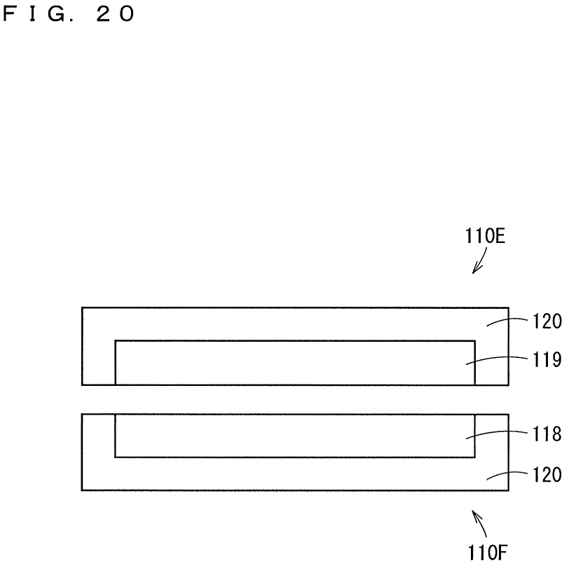

Next, a third preferred embodiment will be described. FIG. 17 is a flowchart illustrating a method of manufacturing the semiconductor device 111 according to the third preferred embodiment. FIG. 18 is a sectional view of a semiconductor substrate 110D after a semiconductor substrate preparation step in the third preferred embodiment. FIG. 19 is a sectional view of the semiconductor substrate 110D after a polycrystalline semiconductor layer formation step in the third preferred embodiment. FIG. 20 is a sectional view of the semiconductor substrates 110E, 110F after a peeling step in the third preferred embodiment. In the third preferred embodiment, the same components as those described in the first and second preferred embodiments are denoted by the same reference numerals, and description thereof is omitted.

### Method of Manufacturing and Structure

As illustrated in FIG. 17, in the third preferred embodiment, the semiconductor substrates 110E, 110F are manufactured by a method different from the methods in the first and second preferred embodiments, and only the method of manufacturing the semiconductor substrates 110E, 110F will be described.

In a semiconductor substrate preparation step (step S31), as illustrated in FIG. 18, a single crystal semiconductor substrate 118 as a first semiconductor substrate and a single crystal semiconductor substrate 119 as a second semiconductor substrate are prepared, and the single crystal semiconductor substrates 118, 119 are disposed with the first main surfaces of the single crystal semiconductor substrates 118, 119 facing each other. The single crystal semiconductor substrates 118, 119 are the same as the single crystal semiconductor substrate 100 illustrated in FIGS. 2 and 3.

Next, a polycrystalline semiconductor layer formation step (step S32) is the same as the polycrystalline semiconductor layer formation step (step S12) in FIG. 1. As illustrated in FIG. 19, a polycrystalline semiconductor layer 120 is formed on second main surfaces and outer peripheral surfaces of the single crystal semiconductor substrates 118, 119.

Next, in a peeling step (step S33), peeling is performed along the interface between the single crystal semiconductor substrate 118 and the single crystal semiconductor substrate 119.

On the other hand, when the outer peripheral surfaces of the single crystal semiconductor substrates 118, 119 are connected by the polycrystalline semiconductor layer 120 and cannot be peeled, processing is performed along the interface from the outer peripheral surface side by a mechanical or optical method, and peeling is performed. There are types of processing using a wire saw as a mechanical method and processing using a laser as an optical method. By performing peeling in the peeling step (step S33), the semiconductor substrates 110E, 110F in which the second main surfaces and the outer peripheral surfaces are covered with the polycrystalline semiconductor layer 120 are obtained as illustrated in FIG. 20.

In the third preferred embodiment as well, in the same manner as in FIG. 6, the grinding step may be performed on the semiconductor substrates 110E, 110F to grind the polycrystalline semiconductor layer 120 and the single crystal semiconductor substrates 118, 119 on the second main surface side of the single crystal semiconductor substrates 118, 119.

### Effects

As described above, the semiconductor substrates 110E, 110F of the third preferred embodiment have the same structure as the semiconductor substrate 110 of the first preferred embodiment, and the same effects can be obtained.

In addition, because the semiconductor substrates 110E, 110F can be formed more efficiently than in the first preferred embodiment, the manufacturing cost of the semiconductor substrates 110E, 110F can be reduced.

The preferred embodiments can be freely combined, and the preferred embodiments can be appropriately modified or omitted.

Hereinafter, various aspects of the present disclosure will be collectively described as appendixes.

### Appendix 1

A semiconductor substrate comprising:
a single crystal semiconductor substrate including a first main surface, a second main surface opposite to the first main surface, and an outer peripheral surface connecting the first main surface and the second main surface; and
a polycrystalline semiconductor layer provided on the outer peripheral surface of the single crystal semiconductor substrate.

### Appendix 2

The semiconductor substrate according to appendix 1, wherein the polycrystalline semiconductor layer is not provided on the first main surface and the second main surface of the single crystal semiconductor substrate.

### Appendix 3

The semiconductor substrate according to appendix 1,
wherein the polycrystalline semiconductor layer is further provided on the second main surface of the single crystal semiconductor substrate.

### Appendix 4

The semiconductor substrate according to any one of appendixes 1 to 3, wherein the first main surface of the single crystal semiconductor substrate is provided with an epitaxial layer.

### Appendix 5

The semiconductor substrate according to any one of appendixes 1 to 4, wherein the single crystal semiconductor substrate is made of silicon carbide.

### Appendix 6

The semiconductor substrate according to any one of appendixes 1 to 4, wherein the polycrystalline semiconductor layer is made of silicon carbide.

### Appendix 7

The semiconductor substrate according to any one of appendixes 1 to 6, wherein the single crystal semiconductor substrate and the polycrystalline semiconductor layer are made of a same material.

### Appendix 8

The semiconductor substrate according to any one of appendixes 1 to 6, wherein the single crystal semiconductor substrate and the polycrystalline semiconductor layer are made of materials different from each other.

### Appendix 9

The semiconductor substrate according to any one of appendixes 1 to 8, wherein the single crystal semiconductor substrate has a thickness of 50 μm or more.

### Appendix 10

The semiconductor substrate according to appendix 3, wherein the polycrystalline semiconductor layer has a thickness of 20 μm or more.

### Appendix 11

A semiconductor device comprising:
the semiconductor substrate according to appendix 4; and
a semiconductor element provided on the epitaxial layer.

### Appendix 12

A method of manufacturing a semiconductor device, the method comprising:
a semiconductor substrate preparation step of preparing a single crystal semiconductor substrate including a first main surface, a second main surface opposite to the first main surface, and an outer peripheral surface connecting the first main surface and the second main surface;
a semiconductor layer formation step of forming a polycrystalline semiconductor layer on the first main surface, the second main surface, and the outer peripheral surface of the single crystal semiconductor substrate; and
a first grinding step of grinding the polycrystalline semiconductor layer and the single crystal semiconductor substrate on the first main surface side of the single crystal semiconductor substrate by a thickness larger than a thickness of the polycrystalline semiconductor layer to expose the first main surface of the single crystal semiconductor substrate.

### Appendix 13

The method of manufacturing a semiconductor device according to appendix 12, wherein the semiconductor layer formation step includes forming the polycrystalline semiconductor layer through vapor phase growth.

### Appendix 14

The method of manufacturing a semiconductor device according to appendix 12 or 13, the method further comprising:
a polishing step of polishing the first main surface of the single crystal semiconductor substrate that has been exposed after the first grinding step;
an epitaxial growth step of forming an epitaxial layer on the first main surface of the single crystal semiconductor substrate that has been polished;
a semiconductor element formation step of forming a semiconductor element on the epitaxial layer; and
a second grinding step of grinding the polycrystalline semiconductor layer and the single crystal semiconductor substrate on the second main surface side of the single crystal semiconductor substrate by a thickness larger than a thickness of the polycrystalline semiconductor layer to expose the second main surface of the single crystal semiconductor substrate.

### Appendix 15

The method of manufacturing a semiconductor device according to any one of appendixes 12 to 14, wherein in the semiconductor layer formation step, the thickness of the polycrystalline semiconductor layer formed immediately below the single crystal semiconductor substrate is smaller than a thickness of the single crystal semiconductor substrate.

### Appendix 16

A method of manufacturing a semiconductor device, the method comprising:
a semiconductor substrate preparation step of preparing a single crystal semiconductor substrate including a first main surface, a second main surface opposite to the first main surface, and an outer peripheral surface connecting the first main surface and the second main surface;
a hydrogen ion layer formation step of forming a hydrogen ion layer on the first main surface of the single crystal semiconductor substrate;
a semiconductor layer formation step of forming a polycrystalline semiconductor layer on the first main surface side, the second main surface, and the outer peripheral surface of the single crystal semiconductor substrate through CVD growth; and
a peeling step of heating the single crystal semiconductor substrate at a high temperature and peeling the single crystal semiconductor substrate along the hydrogen ion layer to expose the first main surface.

### Appendix 17

A method of manufacturing a semiconductor device, the method comprising:
a semiconductor substrate preparation step of preparing a first semiconductor substrate and a second semiconductor substrate each including a first main surface, a second main surface opposite to the first main surface, and an outer peripheral surface connecting the first main surface and the second main surface, the first semiconductor substrate and the second semiconductor substrate being made of a single crystal semiconductor, and disposing the first semiconductor substrate and the second semiconductor substrate in a state where the first main surface of the first semiconductor substrate and the first main surface of the second semiconductor substrate face each other;
a semiconductor layer formation step of forming a polycrystalline semiconductor layer on the second main surface and the outer peripheral surface of each of the first semiconductor substrate and the second semiconductor substrate through CVD growth; and
a peeling step of peeling the first semiconductor substrate and the second semiconductor substrate along an interface between the first semiconductor substrate and the second semiconductor substrate.

While the disclosure has been shown and described in detail, the foregoing description is in all aspects illustrative and not restrictive. It is therefore understood that numerous modifications and variations can be devised.

What is claimed is:

1. A semiconductor substrate comprising:
a single crystal semiconductor substrate including a first main surface, a second main surface opposite to the first main surface, and an outer peripheral surface connecting the first main surface and the second main surface; and
a polycrystalline semiconductor layer provided on the outer peripheral surface of the single crystal semiconductor substrate.

2. The semiconductor substrate according to claim 1, wherein the polycrystalline semiconductor layer is not provided on the first main surface and the second main surface of the single crystal semiconductor substrate.

3. The semiconductor substrate according to claim 1,
wherein the polycrystalline semiconductor layer is further provided on the second main surface of the single crystal semiconductor substrate.

4. The semiconductor substrate according to claim 1, wherein the first main surface of the single crystal semiconductor substrate is provided with an epitaxial layer.

5. The semiconductor substrate according to claim 1, wherein the single crystal semiconductor substrate is made of silicon carbide.

6. The semiconductor substrate according to claim 1, wherein the polycrystalline semiconductor layer is made of silicon carbide.

7. The semiconductor substrate according to claim 1, wherein the single crystal semiconductor substrate and the polycrystalline semiconductor layer are made of a same material.

8. The semiconductor substrate according to claim 1, wherein the single crystal semiconductor substrate and the polycrystalline semiconductor layer are made of materials different from each other.

9. The semiconductor substrate according to claim 1, wherein the single crystal semiconductor substrate has a thickness of 50 μm or more.

10. The semiconductor substrate according to claim 3, wherein the polycrystalline semiconductor layer has a thickness of 20 μm or more.

11. A semiconductor device comprising:
the semiconductor substrate according to claim 4; and
a semiconductor element provided on the epitaxial layer.

12. A method of manufacturing a semiconductor device, the method comprising:
a semiconductor substrate preparation step of preparing a single crystal semiconductor substrate including a first main surface, a second main surface opposite to the first main surface, and an outer peripheral surface connecting the first main surface and the second main surface;
a semiconductor layer formation step of forming a polycrystalline semiconductor layer on the first main surface, the second main surface, and the outer peripheral surface of the single crystal semiconductor substrate; and
a first grinding step of grinding the polycrystalline semiconductor layer and the single crystal semiconductor substrate on the first main surface side of the single crystal semiconductor substrate by a thickness larger than a thickness of the polycrystalline semiconductor layer to expose the first main surface of the single crystal semiconductor substrate.

13. The method of manufacturing a semiconductor device according to claim 12, wherein the semiconductor layer formation step includes forming the polycrystalline semiconductor layer through vapor phase growth.

14. The method of manufacturing a semiconductor device according to claim 12, the method further comprising:
a polishing step of polishing the first main surface of the single crystal semiconductor substrate that has been exposed after the first grinding step;
an epitaxial growth step of forming an epitaxial layer on the first main surface of the single crystal semiconductor substrate that has been polished;
a semiconductor element formation step of forming a semiconductor element on the epitaxial layer; and
a second grinding step of grinding the polycrystalline semiconductor layer and the single crystal semiconductor substrate on the second main surface side of the single crystal semiconductor substrate by a thickness larger than a thickness of the polycrystalline semiconductor layer to expose the second main surface of the single crystal semiconductor substrate.

15. The method of manufacturing a semiconductor device according to claim 12, wherein in the semiconductor layer formation step, the thickness of the polycrystalline semiconductor layer formed immediately below the single crystal semiconductor substrate is smaller than a thickness of the single crystal semiconductor substrate.

16. A method of manufacturing a semiconductor device, the method comprising:
a semiconductor substrate preparation step of preparing a single crystal semiconductor substrate including a first main surface, a second main surface opposite to the first main surface, and an outer peripheral surface connecting the first main surface and the second main surface;
a hydrogen ion layer formation step of forming a hydrogen ion layer on the first main surface of the single crystal semiconductor substrate;
a semiconductor layer formation step of forming a polycrystalline semiconductor layer on the first main surface side, the second main surface, and the outer peripheral surface of the single crystal semiconductor substrate through CVD growth; and
a peeling step of heating the single crystal semiconductor substrate at a high temperature and peeling the single crystal semiconductor substrate along the hydrogen ion layer to expose the first main surface.

17. A method of manufacturing a semiconductor device, the method comprising:
a semiconductor substrate preparation step of preparing a first semiconductor substrate and a second semiconductor substrate each including a first main surface, a second main surface opposite to the first main surface, and an outer peripheral surface connecting the first main surface and the second main surface, the first semiconductor substrate and the second semiconductor substrate being made of a single crystal semiconductor, and disposing the first semiconductor substrate and the second semiconductor substrate in a state where the first main surface of the first semiconductor substrate and the first main surface of the second semiconductor substrate face each other;
a semiconductor layer formation step of forming a polycrystalline semiconductor layer on the second main surface and the outer peripheral surface of each of the first semiconductor substrate and the second semiconductor substrate through CVD growth; and
a peeling step of peeling the first semiconductor substrate and the second semiconductor substrate along an interface between the first semiconductor substrate and the second semiconductor substrate.
